(19) United States
(12) Patent Application Publication
(10) Pub. No.: US 2024/0017350 A1
(43) Pub. Date: Jan. 18, 2024

(54) LASER PROCESSING APPARATUS, METHODS OF OPERATING THE SAME, AND METHODS OF PROCESSING WORKPIECES USING THE SAME

(71) Applicant: ELECTRO SCIENTIFIC INDUSTRIES, INC., Beaverton, OR (US)

(72) Inventors: Jan KLEINERT, Wilsonville, OR (US); Ruolin CHEN, Beaverton, OR (US); James BROOKHYSER, Lake Oswego, OR (US); Mark UNRATH, Portland, OR (US); Honghua HU, San Diego, CA (US)

(73) Assignee: ELECTRO SCIENTIFIC INDUSTRIES, INC., Beaverton, OR (US)

(21) Appl. No.: 18/253,838

(22) PCT Filed: Nov. 23, 2021
(86) PCT No.: PCT/US2021/060504

§ 371 Date: May 22, 2023

Related U.S. Application Data
(60) Provisional application No. 63/131,921, filed on Dec. 30, 2020.

(51) Int. Cl. B23K 26/0622; B23K 26/03

(52) U.S. Cl. CPC B23K 26/0622; B23K 26/03; B23K 2101/42

(57) ABSTRACT

A laser-processing apparatus can carry out a process to form a via in a workpiece, having a first material formed on a second material, by directing laser energy onto the workpiece such that the laser energy is incident upon the first material, wherein the laser energy has a wavelength to which the first material is more reflective than the second material. The apparatus can include a back-reflection sensing system operative to capture a back-reflection signal corresponding to a portion of laser energy directed to the workpiece and reflected by the first material and generate a sensor signal based on the captured back-reflection signal; and a controller communicatively coupled to an output of the back-reflection sensing system, wherein the controller is operative to control a remainder of the process by which the via is formed based on the sensor signal.

### BACKGROUND

### I. Technical Field

Embodiments of the present invention relate to a laser-processing apparatus and methods of operating the same.

### II. Technical Background

Printed circuit boards (PCBs) are typically formed of an electrically conductive layer that has been laminated onto a dielectric substrate. PCBs can be double-sided or multi-layered. A double-sided PCB includes two electrically conductive layers laminated onto opposite sides of a common dielectric substrate. A multi-layered PCB typically includes multiple dielectric substrates with electrically conductive layers interposed therebetween, as well as one or more electrically conductive layers laminated on the outer surfaces thereof.

The dielectric substrate is usually provided as a composite material formed of a matrix material (e.g., epoxy resin) and a reinforcement material (e.g., woven fiberglass cloth). Such a dielectric substrate will necessarily have an inhomogeneous composition, as illustrated in FIG. 1. Referring to FIG. 1, the woven fiberglass cloth (shown as strands of white or grey) can be seen to be surrounded by a matrix material (shown in black). The composition of the dielectric substrate will vary depending on location. For example, at location “A,” the dielectric substrate contains a relatively high amount of reinforcement material and a relatively low amount of matrix material; at location “B,” the dielectric substrate contains only matrix material; and at location “C,” the dielectric substrate contains less reinforcement material than at location “A” but more than at location “B,” and contains more matrix than at location “A” but less than at location “C.” A schematic, cross-sectional view of a portion of a PCB, including a dielectric substrate as discussed with respect to FIG. 1 is shown in FIG. 2. Referring to FIG. 2, an electrical conductor 20 (also referred to herein a “top conductor”) is provided at a first surface of the dielectric substrate 24, and another electrical conductor 24 (also referred to herein as a “bottom conductor”) is provided at a second surface of the dielectric substrate 24. The dielectric substrate 24 is shown to include the matrix material 26 and reinforcement material 28.

Vias, whether blind-hole vias or through-hole vias can be drilled in the PCB using lasers (e.g., using a laser-drilling process). A schematic, cross-sectional view of a blind-hole via, formed in the PCB shown in FIG. 2, is shown in FIG. 3. Referring to FIG. 2, a blind-via hole 30 can be formed using a laser-drilling “punch” process in which a beam of laser energy is directed to a single location on the PCB so as to form an opening in the top conductor 20, and to remove the dielectric substrate 24 so as to expose a portion of the bottom conductor 22 within the blind-via hole 30. However, the matrix and reinforcement materials of the dielectric substrate 24 are often not processed with the same efficiency by the laser; the matrix material is typically processed more readily than the reinforcement material. Also, across different regions of the PCB, there may be variations in surface reflectivity and/or thickness of the top conductor 20. As a result, if the same drilling parameters (e.g., in terms of pulse width, peak pulse power) are used to form blind-via holes at different locations within the dielectric substrate, then there will be some inherent variability in the morphologies between the blind-via holes ultimately produced. Morphological characteristics of a blind-via hole can include the degree to which the top conductor extends over the sidewalls of the hole formed in the dielectric substrate 24 (also known as “overhang”) and the ratio of the diameter of the blind-via hole 30 at the bottom conductor 22 to the diameter of the blind-via hole 30 at the top conductor 20 (also known as “taper”). Generally, it is desirable that each via is characterized by a relatively small overhang and a relatively large taper. Location-dependent variability in morphological characteristics of blind-via holes is thus undesirable for high performance PCBs and their associated processing yield.

The above-noted variability issue can be reduced somewhat by processing the PCB using a laser wavelength that is relatively insensitive to variations in dielectric substrate composition. For example, a carbon dioxide laser can produce laser energy at a wavelength of ˜9.4 μm, which can be linearly absorbed by the matrix and reinforcement materials but predominately reflected by the electrical conductor (i.e., copper) to be exposed by the blind-via hole. It is generally known that more energy (even at laser a laser wavelength of ˜9.4 μm) is required to remove the reinforcement material 28 than to remove the matrix material 26. However, even if the energy needed to remove a portion of the dielectric substrate 24 varies based on the relative amounts of matrix material 26 and reinforcement material 28 therein, the matrix and reinforcement materials of the dielectric substrate 24 can usually be reliably removed without damaging (e.g., melting) the bottom conductor 22.

The above-noted variability issue can be further reduced by using multiple laser pulses to form a single blind-via hole. In this case, the first pulse is applied to form an opening in the top conductor 20 and all subsequent pulses are applied to remove the remaining dielectric substrate 24 without damaging the bottom conductor 22. Proposals to improve upon this “multi-pulse processing” technique typically involve adjusting the pulse energy of the second or subsequent laser pulses based on the intensity of laser light reflected by the bottom conductor 22, which is generally understood to correspond to the size of the area of the bottom conductor 22 that is exposed by the blind-via hole 30.

### SUMMARY

One embodiment of the present invention can be broadly characterized as a laser-processing apparatus for carrying out a process to form a via in a workpiece, having a first material formed on a second material, by directing laser energy onto the workpiece such that the laser energy is incident upon the first material, wherein the laser energy has a wavelength to which the first material is more reflective than the second material. The apparatus can include: a back-reflection sensing system operative to capture a back-reflection signal corresponding to a portion of laser energy directed to the workpiece and reflected by the first material and generate a sensor signal based on the captured back-reflection signal; and a controller communicatively coupled to an output of the back-reflection sensing system, wherein the controller is operative to control a remainder of the process by which the via is formed based on the sensor signal.

Another embodiment of the present invention can be broadly characterized as a method that includes: carrying out a process to form a via in a workpiece, having a first material formed on a second material, by directing a laser pulse onto the workpiece such that the laser pulse is incident upon the first material, wherein the laser energy has a wavelength to which the first material is more reflective than the second material; capturing a back-reflection signal corresponding to a portion of laser energy directed to the workpiece and reflected by the first material; generating a sensor signal based on the based on the captured back-reflection signal; processing the sensor signal to determine how a remainder of the process should be carried out to form the via; and carrying out the remainder of the process based on the processing of the sensor signal.

Yet another embodiment of the present invention can be broadly characterized as a non-transitory computer-readable medium for use with a laser-processing apparatus operative to carry out a process to form a via in a workpiece, having a first material formed on a second material, by directing laser energy onto the workpiece such that the laser energy is incident upon the first material, wherein the laser energy has a wavelength to which the first material is more reflective than the second material, wherein apparatus has a back-reflection sensing system operative to capture a back-reflection signal corresponding to a portion of laser energy directed to the workpiece and reflected by the first material and generate a sensor signal based on the captured back-reflection signal and a controller communicatively coupled to an output of the back-reflection sensing system, and wherein the non-transitory computer-readable medium has stored thereon instructions which, when executed by the controller, causes the controller to control the process by which the via is formed based on the sensor signal.

### BRIEF DESCRIPTION OF THE DRAWINGS

FIG. 1 illustrates an example arrangement of reinforcement material within a matrix material of a composite dielectric substrate, which may be processed with a laser according to embodiments of the present invention.

FIG. 2 illustrates a schematic, cross-sectional view of a portion of a PCB, including a dielectric substrate as discussed with respect to FIG. 1.

FIG. 3 illustrates a schematic, cross-sectional view of a blind-hole via, formed in the PCB shown in FIG. 2.

FIG. 4 schematically illustrates a laser-processing apparatus in accordance with one embodiment of the present invention.

FIG. 5 schematically illustrates a back-reflection sensing system of the laser-processing apparatus shown in FIG. 4, in accordance with one embodiment of the present invention.

FIG. 6 is a graph illustrating a signal intensity of an exemplary back-reflection signal captured by the back-reflection sensing system discussed with respect to FIGS. 4 and 5, as a function of time (i.e., during formation of a blind-via hole), according to embodiments of the present invention.

### DETAILED DESCRIPTION

Example embodiments are described herein with reference to the accompanying drawings. Unless otherwise expressly stated, in the drawings the sizes, positions, etc., of components, features, elements, etc., as well as any distances therebetween, are not necessarily to scale, but are exaggerated for clarity. In the drawings, like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular example embodiments only and is not intended to be limiting. Unless otherwise defined, all terms (including technical and scientific terms) used herein have the same meaning as commonly understood by one of ordinary skill in the art. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first node” and similarly, another node could be termed a “second node”, or vice versa.

Unless indicated otherwise, the term “about,” “thereabout,” “substantially,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Spatially relative terms, such as “below,” “beneath,” “lower,” “above,” and “upper,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

The section headings used herein are for organizational purposes only and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

### I. OVERVIEW

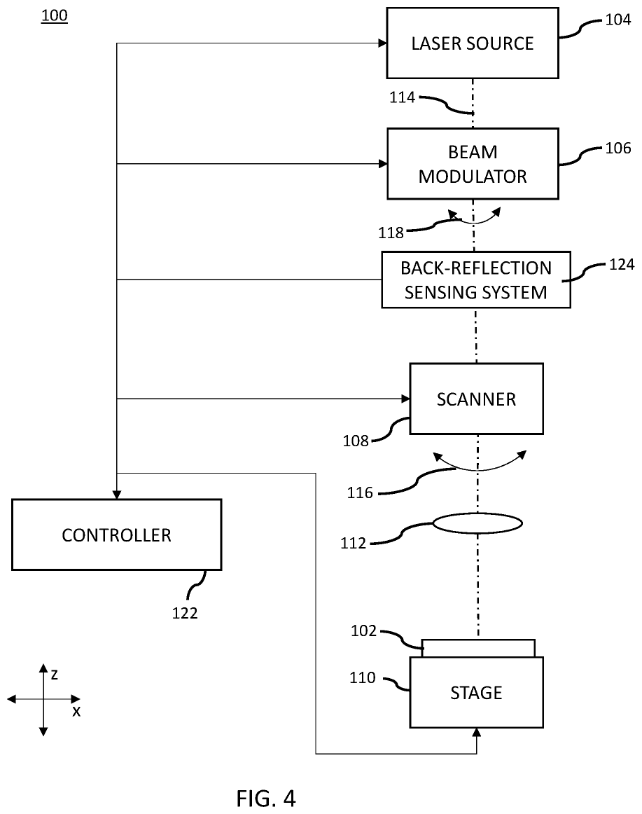

FIG. 4 schematically illustrates a laser-processing apparatus in accordance with one embodiment of the present invention.

Referring to the embodiment shown in FIG. 4, a laser-processing apparatus 100 (also referred to herein simply as an “apparatus”) for processing a workpiece 102 can be characterized as including a laser source 104 for generating a beam of laser energy, a beam modulator 106, a scanner 108, a stage 110 and a scan lens 112.

As discussed in greater detail below, the beam modulator 106 is operative to selectively, and variably, attenuate the beam of laser energy propagating from the laser source 104. As a result, the beam of laser energy propagating along beam path 114 from the beam modulator 106 may have an optical power that is less than that of the beam of laser energy propagating along beam path 114 into the beam modulator 106. As used herein, the term “beam path” refers to the path along which laser energy in the beam of laser energy travels as it propagates from the laser source 104 to the scan lens 112.

The scanner 108 is operative to diffract, reflect, refract, or the like, or any combination thereof, the beam of laser energy generated by the laser source 104 and, optionally, deflected by the beam modulator 106 (i.e., to “deflect” the beam of laser energy) so as to deflect the beam path 114 to scan lens 112. When deflecting the beam path 114 to the scan lens 112, the scanner 108 can deflect the beam path 114 by any angle (e.g., as measured relative to the optical axis of the scan lens 112) within a range of angles (as indicated at 116).

Laser energy deflected to a scan lens 112 is typically focused by the scan lens 112 and transmitted to propagate along a beam axis so as to be delivered to a workpiece 102. Laser energy delivered to a workpiece 102 may be characterized as having a Gaussian-type spatial intensity profile or a non-Gaussian-type (i.e., “shaped”) spatial intensity profile (e.g., a “top-hat” spatial intensity profile, a super-Gaussian spatial intensity profile, etc.).

As used herein, the term “spot size” refers to the diameter or maximum spatial width of the beam of laser energy delivered at a location (also referred to as a “process spot,” “spot location” or, more simply, a “spot”) where the beam axis intersects a region of the workpiece 102 that is to be, at least partially, processed by the delivered beam of laser energy. For purposes of discussion herein, spot size is measured as a radial or transverse distance from the beam axis to where the optical intensity drops to, at least, 1/e2 of the optical intensity at the beam axis. Generally, the spot size of the beam of laser energy will be at a minimum at the beam waist. Once delivered to the workpiece 102, laser energy within the beam can be characterized as impinging the workpiece 102 at a spot size in a range from 2 μm to 200 μm. It will be appreciated, however, that the spot size can be made smaller than 2 μm or larger than 200 μm. Thus, the beam of laser energy delivered to the workpiece 102 can have a spot size greater than, less than, or equal to 2 μm, 3 μm, 5 μm, 7 μm, 10 μm, 15 μm, 30 μm, 35 μm, 40 μm, 45 μm, 50 μm, 55 μm, 80 μm, 100 μm, 150 μm, 200 μm, etc., or between any of these values.

The apparatus 100 may also include one or more other optical components (e.g., beam traps, beam expanders, beam shapers, beam splitters, apertures, filters, collimators, lenses, mirrors, prisms, polarizers, phase retarders, diffractive optical elements (commonly known in the art as DOEs), refractive optical elements (commonly known in the art as ROEs), or the like or any combination thereof) to focus, expand, collimate, shape, polarize, filter, split, combine, crop, absorb, or otherwise modify, condition, direct, etc., the beam of laser energy as it propagates along beam path 114.

A. Laser Source

In one embodiment, the laser source 104 is operative to generate laser pulses. As such, the laser source 104 may include a pulse laser source, a CW laser source, a QCW laser source, a burst mode laser, or the like or any combination thereof. In the event that the laser source 104 includes a QCW or CW laser source, the laser source 104 may be operated in a pulsed mode, or may be operated in a non-pulsed mode but further include a pulse gating unit (e.g., an acousto-optic (AO) modulator (AOM), a beam chopper, etc.) to temporally modulate beam of laser radiation output from the QCW or CW laser source. Although not illustrated, the apparatus 100 may optionally include one or more harmonic generation crystals (also known as “wavelength conversion crystals”) configured to convert a wavelength of light output by the laser source 104. In another embodiment, however, the laser source 104 may be provided as a QCW laser source or a CW laser source and not include a pulse gating unit. Thus, the laser source 104 can be broadly characterized as operative to generate a beam of laser energy, which may manifested as a series of laser pulses or as a continuous or quasi-continuous laser beam, which can thereafter be propagated along the beam path 114. Although many embodiments discussed herein make reference to laser pulses, it should be recognized that continuous or quasi-continuous beams may alternatively, or additionally, be employed whenever appropriate or desired.

Laser energy output by the laser source 104 can have one or more wavelengths in the ultraviolet (UV), visible or infrared (IR) range of the electromagnetic spectrum. Laser energy in the UV range of the electromagnetic spectrum may have one or more wavelengths in a range from 10 nm (or thereabout) to 385 nm (or thereabout), such as 100 nm, 121 nm, 124 nm, 157 nm, 200 nm, 334 nm, 337 nm, 351 nm, 380 nm, etc., or between any of these values. Laser energy in the visible, green range of the electromagnetic spectrum may have one or more wavelengths in a range from 500 nm (or thereabout) to 560 nm (or thereabout), such as 511 nm, 515 nm, 530 nm, 532 nm, 543 nm, 568 nm, etc., or between any of these values. Laser energy in the IR range of the electromagnetic spectrum may have one or more wavelengths in a range from 750 nm (or thereabout) to 15 μm (or thereabout), such as 600 nm to 1000 nm, 752.5 nm, 780 nm to 1060 nm, 799.3 nm, 980 nm, 1047 nm, 1053 nm, 1060 nm, 1064 nm, 1080 nm, 1090 nm, 1152 nm, 1150 nm to 1350 nm, 1540 nm, 2.6 μm to 4 μm, 4.8 μm to 8.3 μm, 9.4 μm, 10.6 μm, etc., or between any of these values.

When the beam of laser energy is manifested as a series of laser pulses, the laser pulses output by the laser source 104 can have a pulse width or pulse duration (i.e., based on the full-width at half-maximum (FWHM) of the optical power in the pulse versus time) that is in a range from 10 fs to 900 ms. It will be appreciated, however, that the pulse duration can be made smaller than 10 fs or larger than 900 ms. Thus, at least one laser pulse output by the laser source 104 can have a pulse duration less than, greater than or equal to 10 fs, 15 fs, 30 fs, 50 fs, 100 fs, 150 fs, 200 fs, 300 fs, 500 fs, 600 fs, 750 fs, 800 fs, 850 fs, 900 fs, 950 fs, 1 ps, 2 ps, 3 ps, 4 ps, 5 ps, 7 ps, 10 ps, 15 ps, 25 ps, 50 ps, 75 ps, 100 ps, 200 ps, 500 ps, 1 ns, 1.5 ns, 2 ns, 5 ns, 10 ns, 20 ns, 50 ns, 100 ns, 200 ns, 400 ns, 800 ns, 1000 ns, 2 μs, 5 μs, 10 μs, 15 μs, 20 μs, 25 μs, 30 μs, 40 μs, 50 μs, 100 μs, 300 μs, 500 μs, 900 μs, 1 ms, 2 ms, 5 ms, 10 ms, 20 ms, 50 ms, 100 ms, 300 ms, 500 ms, 900 ms, 1 s, etc., or between any of these values.

Laser pulses output by the laser source 104 can have an average power in a range from 5 mW to 50 kW. It will be appreciated, however, that the average power can be made smaller than 5 mW or larger than 50 kW. Thus, laser pulses output by the laser source 104 can have an average power less than, greater than or equal to 5 mW, 10 mW, 15 mW, 20 mW, 25 mW, 50 mW, 75 mW, 100 mW, 300 mW, 500 mW, 800 mW, 1 W, 2 W, 3 W, 4 W, 5 W, 6 W, 7 W, 10 W, 15 W, 18 W, 25 W, 30 W, 50 W, 60 W, 100 W, 150 W, 200 W, 250 W, 500 W, 2 kW, 3 kW, 20 kW, 50 kW, etc., or between any of these values.

Laser pulses can be output by the laser source 104 at a pulse repetition rate in a range from 5 kHz to 5 GHz. It will be appreciated, however, that the pulse repetition rate can be less than 5 kHz or larger than 5 GHz. Thus, laser pulses can be output by the laser source 104 at a pulse repetition rate less than, greater than or equal to 5 kHz, 50 kHz, 100 kHz, 175 kHz, 225 kHz, 250 kHz, 275 kHz, 500 kHz, 800 kHz, 900 kHz, 1 MHz, 1.5 MHz, 1.8 MHz, 1.9 MHz, 2 MHz, 2.5 MHz, 3 MHz, 4 MHz, 5 MHz, 10 MHz, 20 MHz, 50 MHz, 60 MHz, 100 MHz, 150 MHz, 200 MHz, 250 MHz, 300 MHz, 350 MHz, 500 MHz, 550 MHz, 600 MHz, 900 MHz, 2 GHz, 10 GHz, etc., or between any of these values.

In addition to wavelength, average power and, when the beam of laser energy is manifested as a series of laser pulses, pulse duration and pulse repetition rate, the beam of laser energy delivered to the workpiece 102 can be characterized by one or more other characteristics such as pulse energy, peak power, etc., which can be selected (e.g., optionally based on one or more other characteristics such as wavelength, pulse duration, average power and pulse repetition rate, spot size, etc.) to irradiate the workpiece 102 at the process spot at an optical intensity (measured in W/cm2), fluence (measured in J/cm2), etc., sufficient to process the workpiece 102 (e.g., to form one or more features).

Examples of types of lasers that the laser source 104 may be characterized as gas lasers (e.g., carbon dioxide lasers, carbon monoxide lasers, excimer lasers, etc.), solid-state lasers (e.g., Nd:YAG lasers, etc.), rod lasers, fiber lasers, photonic crystal rod/fiber lasers, passively mode-locked solid-state bulk or fiber lasers, dye lasers, mode-locked diode lasers, pulsed lasers (e.g., ms-, ns-, ps-, fs-pulsed lasers), CW lasers, QCW lasers, or the like or any combination thereof. Depending upon their configuration, gas lasers (e.g., carbon dioxide lasers, etc.) may be configured to operate in one or more modes (e.g., in CW mode, QCW mode, pulsed mode, or any combination thereof).

B. Beam Modulator

As mentioned above, the beam modulator 106 is operative to selectively, and variably, attenuate the beam of laser energy propagating from the laser source 104. Examples of the beam modulator 106 can include one or more systems such as a variable neutral density filter, an acousto-optical (AO) modulator (AOM), an AO deflector (AOD), a liquid crystal variable attenuator (LCVA), a micro-electro-mechanical system (MEMS)-based VOA, an optical attenuator wheel, a polarizer/waveplate filter, or the like or any combination thereof.

i. Embodiments Concerning an AOD as the Beam Modulator

When the beam modulator 106 is provided as one or more AOMs or AODs, or any combination thereof, the beam modulator 106 may also be operated to diffract the beam of laser energy generated by the laser source 104 and so as to deflect the beam path 114 relative to the scanner 108. In one embodiment, the beam modulator 106 can also be operated to impart movement of the beam axis relative to the workpiece 102 along the X-axis (or direction), a Y-axis (or direction), or a combination thereof (e.g., by deflecting of the beam path 114 within a range of angles, as indicated at 118). Although not illustrated, the Y-axis (or Y-direction) will be understood to refer to an axis (or direction) that is orthogonal to the illustrated X- and Z-axes (or directions).

In one embodiment, the beam modulator 106 can be provided as an AO deflector (AOD) system, which includes one or more AODs, each having an AO cell formed of a material such as crystalline germanium (Ge), gallium arsenide (GaAs), wulfenite (PbMoO4), tellurium dioxide (TeO2), crystalline quartz, glassy SiO2, arsenic trisulfide (As2S3), lithium niobate (LiNbO3), or the like or any combination thereof. It will be appreciated that the material from which the AO cell is formed will depend upon the wavelength of the laser energy that propagates along the beam path 114 so as to be incident upon the AO cell. For example, a material such as crystalline germanium can be used where the wavelength of laser energy to be deflected is in a range from 2 μm (or thereabout) to 20 μm (or thereabout), materials such as gallium arsenide and arsenic trisulfide can be used where the wavelength of the beam of laser energy to be deflected is in a range from 1 μm (or thereabout) to 11 μm (or thereabout), and materials such as glassy SiO2, quartz, lithium niobate, wulfenite, and tellurium dioxide can be used where the wavelength of laser energy to be deflected is in a range from 200 nm (or thereabout) to 5 μm (or thereabout).

As will be recognized by those of ordinary skill, AO technologies (e.g., AODs, AOMs, etc.) utilize diffraction effects caused by one or more acoustic waves propagating through the AO cell (i.e., along a “diffraction axis” of the AOD) to diffract an incident optical wave (i.e., a beam of laser energy, in the context of the present application) contemporaneously propagating through the AO cell (i.e., along an “optical axis” within the AOD). Diffracting the incident beam of laser energy produces a diffraction pattern that typically includes zeroth- and first-order diffraction peaks, and may also include other higher-order diffraction peaks (e.g., second-order, third-order, etc.). As is known in the art, the portion of the diffracted beam of laser energy in the zeroth-order diffraction peak is referred to as a “zeroth-order” beam, the portion of the diffracted beam of laser energy in the first-order diffraction peak is referred to as a “first-order” beam, and so on. Generally, the zeroth-order beam and other diffracted-order beams (e.g., the first-order beam, etc.) propagate along different beam paths upon exiting the AO cell (e.g., through an optical output side of the AO cell). For example, the zeroth-order beam propagates along a zeroth-order beam path, the first-order beam propagates along a first-order beam path, and so on. Unless otherwise expressly stated herein, the beam path 114 exiting the AO cell corresponds to the first-order beam path. Although not illustrated, the apparatus 100 will include one or more beam dumps or traps arranged and configured to absorb laser energy propagating from the beam modulator 106 along the zeroth-order beam path or any beam paths other than the first-order beam path, as is known in the art.

Acoustic waves are typically launched into the AO cell by applying an RF drive signal (e.g., from one or more drivers of the beam modulator 106) to the ultrasonic transducer element. Characteristics of the RF drive signal (e.g., amplitude, frequency, phase, etc.) can be controlled (e.g., based on one or more control signals output by the controller 122, a component-specific controller, or the like or any combination thereof) to adjust the manner with which the incident optical wave is diffracted.

For example, the frequency of the applied RF drive signal will determine the angle to which the beam path 114 is deflected. As is known in the art, the angle, Θ, by which the beam path 114 is deflected is can be calculated as follows:

θ=λ·f/v

where λ is the optical wavelength of beam of laser energy, f is the frequency of the applied RF drive signal, and v is the velocity of the acoustic wave in the AO cell. If the frequency of the applied RF drive signal is composed of multiple frequencies, then the beam path 114 will be deflected simultaneously by multiple angles.

Further, the amplitude of an applied RF drive signal can have an effect on the diffraction efficiency of the AOD. As used herein, the term “diffraction efficiency” refers to the proportion of energy in a beam of laser energy incident upon an AOD that gets diffracted within the AO cell of the AOD into the first-order beam. Diffraction efficiency may thus be represented as the ratio of the optical power in the first-order beam produced by the AOD to the optical power of the incident beam of laser energy incident upon the AOD. Thus, the amplitude of the applied RF drive signal can have a large effect on the optical power in the first-order beam output by the AOD. Thus, the beam modulator 106 can be operated to desirably attenuate an incident beam of laser energy upon being driven by an applied RF signal having a desired or otherwise suitable amplitude. It should also be noted that the diffraction efficiency of an AOD can also change as a function of the frequency of the RF drive signal applied to drive the AOD.

The axis (also referred to herein as the “rotation axis”) about which the beam path 114 exiting the AO cell is rotated (e.g., relative to the beam path 114 as it is incident upon the AO cell) is orthogonal to both the diffraction axis of the AO cell and the optical axis along which the incident beam of laser energy propagates within the AO cell when the AOD is operated or driven to diffract the incident beam of laser energy. The AOD thus deflects an incident beam path 114 within a plane (also referred to herein as a “plane of deflection”) that contains (or is otherwise generally parallel to) the diffraction axis of the AO cell and the optical axis within the AO cell. The spatial extent across which an AOD can deflect the beam path 114 within the plane of deflection is herein referred to as the “scan field” of that AOD. Accordingly, the first scan field of the beam modulator 106 can be considered to correspond to the scan field of a single AOD (e.g., in the event the beam modulator 106 includes a single AOD) or to correspond to combined scan fields of multiple AODs (e.g., in the event the beam modulator 106 includes multiple AODs).

During operation of the beam modulator 106, RF drive signals are repeatedly applied to one or more ultrasonic transducers of the beam modulator 106. The rate with which the RF drive signals are applied is also referred to as the “update rate” or “refresh rate.” For example, the update rate of the beam modulator 106 can be greater than, equal to or less than 8 kHz, 10 kHz, 20 kHz, 30 kHz, 40 kHz, 50 kHz, 75 kHz, 80 kHz, 100 kHz, 250 kHz, 500 kHz, 750 kHz, 1 MHz, 5 MHz, 10 MHz, 20 MHz, 40 MHz, 50 MHz, 75 MHz, 100 MHz, 125 MHz, 150 MHz, 175 MHz, 200 MHz, 225 MHz, 250 MHz, etc., or between any of these values.

Additional Discussion Concerning Use of the Beam Modulator to Impart Movement of the Beam Axis

In one embodiment, the beam modulator 106 can be operated so as to impart movement of the beam axis relative to the workpiece 102 (i.e., either alone or in conjunction with the scanner 108). Movement of the beam axis by the beam modulator 106 is generally limited such that the process spot can be scanned, moved or otherwise positioned within a first scan field projected by a scan lens 112. Generally, and depending upon one or more factors such as the configuration of the beam modulator 106, the location of the beam modulator 106 along the beam path 114, the beam size of the beam of laser energy incident upon the beam modulator 106, the spot size, etc., the first scan field may extend, in any of the X- or Y-directions, to a distance that is less than, greater than or equal to 0.01 mm, 0.04 mm, 0.1 mm, 0.5 mm, 1.0 mm, 1.4 mm, 1.5 mm, 1.8 mm, 2 mm, 2.5 mm, 3.0 mm, 3.5 mm, 4.0 mm, 4.2 mm, 5 mm, 10 mm, 25 mm, 50 mm, 60 mm, etc., or between any of these values. As used herein, the term “beam size” refers to the diameter or width of the beam of laser energy, and can be measured as a radial or transverse distance from the beam axis to where the optical intensity drops to 1/e2 of the optical intensity at the axis of propagation along the beam path 114. A maximum dimension of the first scan field (e.g., in a plane containing the X- and Y-axes, herein referred to as the “X-Y plane”) may be greater than, equal to or less than a maximum dimension (as measured in the X-Y plane) of a feature (e.g., an opening, a recess, a via, a trench, etc.) to be formed in the workpiece 102.

In one embodiment, the AOD system includes at least one (e.g., one, two, three, four, five, six, etc.) single-element AOD, at least one (e.g., one, two, three, four, five, six, etc.) multi-element AOD, or the like or any combination thereof. An AOD system including only one AOD is herein referred to as a “single-cell AOD system,” and an AOD system including more than one AOD is herein referred to as a “multi-cell AOD system.” As used herein, a “single-element” AOD refers to an AOD having only one ultrasonic transducer element acoustically coupled to the AO cell, whereas a “multi-element” AOD includes at least two ultrasonic transducer elements acoustically coupled to a common AO cell. The AOD system may be provided as single-axis AOD system (e.g., operative to deflect the beam axis along a single axis) or as a multi-axis AOD system (e.g., operative to deflect the beam axis along one or more axes, such as along the X-axis, along the Y-axis, or any combination thereof) by deflecting the beam path 114 in a corresponding manner. Generally, a multi-axis AOD system can be provided as a single- or multi-cell AOD system. A multi-cell, multi-axis AOD system typically includes multiple AODs, each operative to deflect the beam axis along a different axis. For example, a multi-cell, multi-axis system can include a first AOD (e.g., a single- or multi-element AOD system) operative to deflect the beam axis along one axis (e.g., along the X-axis), and a second AOD (e.g., a single- or multi-element AOD) operative to deflect the beam axis along a second axis (e.g., along the Y-axis). A single-cell, multi-axis system typically includes a single AOD operative to deflect the beam axis along two axes (e.g., along the X- and Y-axes). For example, a single-cell, multi-axis system can include at least two ultrasonic transducer elements acoustically coupled to orthogonally-arranged planes, facets, sides, etc., of a common AO cell.

The beam modulator 106 can be characterized as having a “first positioning rate,” which refers to the rate with which the beam modulator 106 positions the process spot at any location within the first scan field (thus moving the beam axis). This range is also referred to herein as the first positioning bandwidth. The inverse of the first positioning rate is herein referred to as the “first positioning period,” and thus refers to the minimum amount of time that elapses before the position of the process spot is changed from one location within the first scan field to another location within the first scan field. Thus, the beam modulator 106 can be characterized as having a first positioning period that is greater than, equal to or less than 200 μs, 125 μs, 100 μs, 50 μs, 33 μs, 25 μs, 20 μs, 15 μs, 13.3 μs, 12.5 μs, 10 μs, 4 μs, 2 μs, 1.3 μs, 1 μs, 0.2 μs, 0.1 μs, 0.05 μs, 0.025 μs, 0.02 μs, 0.013 μs, 0.01 μs, 0.008 μs, 0.0067 μs, 0.0057 μs, 0.0044 μs, 0.004 μs, etc., or between any of these values.

When the beam of laser energy output by the laser source 104 is manifested as a series of laser pulses, the beam modulator 106 can be operated to deflect the beam path 114 by different angles. In one embodiment, the update rate is greater than or equal to the pulse duration of each of the laser pulses. Accordingly, a laser pulse can transit through the AO cell of an AOD while the AOD is driven at a fixed RF drive frequency (or a fixed set of RF drive frequencies). Maintaining a fixed RF drive frequency (or a fixed set of RF drive frequencies) applied to an AOD while a laser pulse is transiting through the AO cell of the AOD generally results in uniformly deflecting the laser pulse for the entire pulse duration of the laser pulse and, so, can also be referred to as “whole-pulse deflection.” In another embodiment, however, the update rate can be less than the pulse duration of a laser pulse; so the laser pulse can transit through the AO cell of the AOD while the RF drive frequency (or the frequencies within the set of RF drive frequencies) is varied. Varying an RF drive frequency applied to an AOD while a laser pulse is transiting through the AO cell of the AOD can result in temporally-dividing the laser pulse input to the AOD and, so, can also be referred to as “partial-pulse deflection” or “pulse slicing.” Varying the amplitude of the applied RF drive signal (e.g., either to zero or some nominal amplitude where an insignificant proportion of energy is diffracted into the first-order beam path) to reduce the diffraction efficiency of the AOD to either zero or to a significant degree (i.e., such that substantially of the laser energy incident upon the AOD propagates along zeroth-order beam path) can also result in temporally-dividing the laser pulse input to the AOD (i.e., pulse slicing).

When pulse slicing is performed, the laser pulse exiting the AOD will have a pulse duration that is less than the pulse duration of the laser pulse that was input to the AOD. As used herein, the laser pulse that is input to the AOD is also referred to as a “mother pulse,” and the laser pulse that is temporally-divided from the mother pulse and exits the AOD along the beam path 114 is also referred to herein as a “pulse slice.” Although pulse slicing techniques are described herein as being applied to temporally-divide a laser pulse, it will be appreciated that these techniques can likewise be applied to temporally-divide a beam of laser energy manifested as a continuous or quasi-continuous laser beam.

C. Scanner

Generally, the scanner 108 is operative to impart movement of the beam axis relative to the workpiece 102 along the X-axis (or direction), the Y-axis (or direction), or a combination thereof.

Movement of the beam axis relative to the workpiece 102, as imparted by the scanner 108, is generally limited such that the process spot can be scanned, moved or otherwise positioned within a second scan field projected by a scan lens 112. Generally, and depending upon one or more factors such as the configuration of the scanner 108, the location of the scanner 108 along the beam path 114, the beam size of the beam of laser energy incident upon the scanner 108, the spot size, etc., the second scan field may extend, in any of the X- or Y-directions to a distance that is greater than a corresponding distance of the first scan field. In view of the above, the second scan field may extend, in any of the X- or Y-directions, to a distance that is less than, greater than or equal to 1 mm, 25 mm, 50 mm, 75 mm, 100 mm, 250 mm, 500 mm, 750 mm, 1 cm, 25 cm, 50 cm, 75 cm, 1 m, 1.25 m, 1.5 m, etc., or between any of these values. A maximum dimension of the second scan field (e.g., in the X-Y plane) may be greater than, equal to or less than a maximum dimension (as measured in the X-Y plane) of a feature (e.g., an opening, a recess, a via, a trench, a scribe line, a conductive trace, etc.) to be formed in the workpiece 102.

In view of the configuration described herein, it should be recognized that any movement of the beam axis imparted by the beam modulator 106 can be superimposed by movement of the beam axis imparted by the scanner 108. Thus, the scanner 108 is operative to scan the first scan field within the second scan field.

Generally, the positioning rate with which the scanner 108 is capable of positioning the process spot at any location within the second scan field (thus moving the beam axis within the second scan field and/or scanning the first scan field within the second scan field) spans a range (also referred to herein as the “second positioning bandwidth”) that is less than the first positioning bandwidth. In one embodiment, the second positioning bandwidth is in a range from 500 Hz (or thereabout) to 8 kHz (or thereabout). For example, the second positioning bandwidth can be greater than, equal to or less than 500 Hz, 750 Hz, 1 kHz, 1.25 kHz, 1.5 kHz, 1.75 kHz, 2 kHz, 2.5 kHz, 3 kHz, 3.5 kHz, 4 kHz, 4.5 kHz, 5 kHz, 5.5 kHz, 6 kHz, 6.5 kHz, 7 kHz, 7.5 kHz, 8 kHz, etc., or between any of these values.

In one embodiment, the scanner 108 can be provided as a galvanometer mirror system including two galvanometer mirror components, i.e., a first galvanometer mirror component (e.g., an X-axis galvanometer mirror component) arranged to impart movement of the beam axis relative to the workpiece 102 along the X-axis and a second galvanometer mirror component (e.g., a Y-axis galvanometer mirror component) arranged to impart movement of the beam axis relative to the workpiece 102 along the Y-axis. In another embodiment, however, the scanner 108 may be provided as a galvanometer mirror system including only a single galvanometer mirror component arranged to impart movement of the beam axis relative to the workpiece 102 along the X- and Y-axes. In yet other embodiments, the scanner 108 may be provided as a rotating polygon mirror system, an AOD system, or the like or any combination thereof.

D. Stage

The stage 110 is operative to impart movement of a workpiece 102 relative to the scan lens 112, and, consequently, impart movement of the workpiece 102 relative to the beam axis. Movement of a workpiece 102 relative to the beam axis is generally limited such that the process spot can be scanned, moved or otherwise positioned within a third scan field. Depending upon one or more factors such as the configuration of the stage 110, the third scan field may extend, in the X-direction, the Y-direction, or any combination thereof, to a distance that is greater than or equal to a corresponding distance of the second scan field. Generally, however, a maximum dimension of the third scan field (e.g., in the X-Y plane) will be greater than or equal to a corresponding maximum dimension (as measured in the X-Y plane) of any feature to be formed in the workpiece 102. Optionally, the stage 110 may be operative to move the workpiece 102 relative to the beam axis within a scan field that extends in the Z-direction (e.g., over a range between 1 mm and 50 mm). Thus, the third scan field may extend along the X-, Y- and/or Z-directions.

As described thus far, the apparatus 100 could employ a so-called “stacked” positioning system as the stage 110, which enables the workpiece 102 to be moved while positions of other components such as the beam modulator 106, scanner 108, scan lens 112, etc., are kept stationary within the apparatus 100 (e.g., via one or more supports, frames, etc., as is known in the art) relative to the workpiece 102. In another embodiment, the stage 110 may be arranged and operative to move one or more components such as the beam modulator 106, scanner 108, scan lens 112, or the like or any combination thereof, and the workpiece 102 may be kept stationary.

In yet another embodiment, the stage 110 can be provided as a so-called “split-axis” positioning system in which one or more components such as the beam modulator 106, scanner 108, scan lens 112, or the like or any combination thereof, are carried by one or more linear or rotational stages (e.g., mounted on a frame, gantry, etc.) and the workpiece 102 is carried by one or more other linear or rotational stages. In such an embodiment, the stage 110 includes one or more linear or rotational stages arranged and operative to move one or more components such as a scan head (e.g., including the scanner 108 and scan lens 112) and one or more linear or rotational stages arranged and operative to move the workpiece 102. For example, the stage 110 may include a Y-stage for imparting movement of the workpiece 102 along the Y-direction and an X-stage for imparting movement of the scan head along the X-direction.

In one embodiment in which the stage 110 includes a Z-stage, the Z-stage may be arranged and configured to move the workpiece 102 along the Z-direction. In this case, the Z-stage may be carried by one or more of the other aforementioned stages for moving or positioning the workpiece 102, may carry one or more of the other aforementioned stages for moving or positioning the workpiece 102, or any combination thereof. In another embodiment in which the stage 110 includes a Z-stage, the Z-stage may be arranged and configured to move the scan head along the Z-direction. Thus, in the case where the stage 110 is provided as a split-stage positioning system, the Z-stage may carry, or be carried by, the X-stage. Moving the workpiece 102 or the scan head along the Z-direction can result in a change in spot size at the workpiece 102.

In still another embodiment, one or more components such as the scanner 108, scan lens 112, etc., may be carried by an articulated, multi-axis robotic arm (e.g., a 2-, 3-, 4-, 5-, or 6-axis arm). In such an embodiment, the scanner 108 and/or scan lens 112 may, optionally, be carried by an end effector of the robotic arm. In yet another embodiment, the workpiece 102 may be carried directly on an end effector of an articulated, multi-axis robotic arm (i.e., without the stage 110). In still another embodiment, the stage 110 may be carried on an end effector of an articulated, multi-axis robotic arm.

E. Scan Lens

The scan lens 112 (e.g., provided as either a simple lens, or a compound lens) is generally configured to focus the beam of laser energy directed along the beam path, typically so as to produce a beam waist that can be positioned at or near the desired process spot. The scan lens 112 may be provided as an non-telecentric f-theta lens (as shown), a telecentric f-theta lens, an axicon lens (in which case, a series of beam waists are produced, yielding a plurality of process spots displaced from one another along the beam axis), or the like or any combination thereof.

In one embodiment, the scan lens 112 is provided as a fixed-focal length lens and is coupled to a scan lens positioner (e.g., a lens actuator, not shown) operative to move the scan lens 112 (e.g., so as to change the position of the beam waist along the beam axis). For example, the lens actuator may be provided as a voice coil operative to linearly translate the scan lens 112 along the Z-direction. In this case, the scan lens 112 may be formed of a material such as fused silica, optical glass, zinc selenide, zinc sulfide, germanium, gallium arsenide, magnesium fluoride, etc. In another embodiment, the scan lens 112 is provided as a variable-focal length lens (e.g., a zoom lens, or a so-called “liquid lens” incorporating technologies currently offered by COGNEX, VARIOPTIC, etc.) capable of being actuated (e.g., via a lens actuator) to change the position of the beam waist along the beam axis. Changing the position of the beam waist along the beam axis can result in a change in spot size at the workpiece 102.

In an embodiment in which the apparatus 100 includes a lens actuator, the lens actuator may be coupled to the scan lens 112 (e.g., so as to enable movement of the scan lens 112 within the scan head, relative to the scanner 108). Alternatively, the lens actuator may be coupled to the scan head (e.g., so as to enable movement of the scan head itself, in which case the scan lens 112 and the scanner 108 would move together). In another embodiment, the scan lens 112 and the scanner 108 are integrated into different housings (e.g., such that the housing in which the scan lens 112 is integrated is movable relative to the housing in which the scanner 108 is integrated).

F. Controller

Generally, the apparatus 100 includes one or more controllers, such as controller 122, to control, or facilitate control of, the operation of the apparatus 100. In one embodiment, the controller 122 is communicatively coupled (e.g., over one or more wired or wireless, serial or parallel, communications links, such as USB, RS-232, Ethernet, Firewire, Wi-Fi, RFID, NFC, Bluetooth, Li-Fi, SERCOS, MARCO, EtherCAT, or the like or any combination thereof) to one or more components of the apparatus 100, such as the laser source 104, the beam modulator 106, the scanner 108, stage 110, the lens actuator, the scan lens 112 (when provided as a variable-focal length lens), etc., which are thus operative in response to one or more control signals output by the controller 122.

For example, the controller 122 may control an operation of the beam modulator 106 to selectively, and variably, attenuate the beam of laser energy incident thereto, to deflect the beam path 114 (e.g., to impart relative movement between the beam axis and the workpiece so as to cause relative movement between the process spot and the workpiece 102 along a path or trajectory (also referred to herein as a “process trajectory”)), or a combination thereof. Likewise, the controller 122 can control an operation of the scanner 108, the stage 110, or any combination thereof, to impart relative movement between the beam axis and the workpiece so as to cause relative movement between the process spot and the workpiece 102 along a process trajectory.

Generally, the controller 122 includes one or more processors operative to generate the aforementioned control signals upon executing instructions. A processor can be provided as a programmable processor (e.g., including one or more general purpose computer processors, microprocessors, digital signal processors, or the like or any combination thereof) operative to execute the instructions. Instructions executable by the processor(s) may be implemented software, firmware, etc., or in any suitable form of circuitry including programmable logic devices (PLDs), field-programmable gate arrays (FPGAs), field-programmable object arrays (FPOAs), application-specific integrated circuits (ASICs)—including digital, analog and mixed analog/digital circuitry—or the like, or any combination thereof. Execution of instructions can be performed on one processor, distributed among processors, made parallel across processors within a device or across a network of devices, or the like or any combination thereof.

In one embodiment, the controller 122 includes tangible media such as computer memory, which is accessible (e.g., via one or more wired or wireless communications links) by the processor. As used herein, “computer memory” includes magnetic media (e.g., magnetic tape, hard disk drive, etc.), optical discs, volatile or non-volatile semiconductor memory (e.g., RAM, ROM, NAND-type flash memory, NOR-type flash memory, SONOS memory, etc.), etc., and may be accessed locally, remotely (e.g., across a network), or a combination thereof. Generally, the instructions may be stored as computer software (e.g., executable code, files, instructions, etc., library files, etc.), which can be readily authored by artisans, from the descriptions provided herein, e.g., written in C, C++, Visual Basic, Java, Python, Tel, Perl, Scheme, Ruby, assembly language, hardware description language (e.g., VHDL, VERILOG, etc.), etc. Computer software is commonly stored in one or more data structures conveyed by computer memory.

Although not shown, one or more drivers (e.g., RF drivers, servo drivers, line drivers, power sources, etc.) can be communicatively coupled to an input of one or more components such as the laser source 104, the beam modulator 106, the scanner 108, the stage 110, the lens actuator, the scan lens 112 (when provided as a variable-focal length lens), etc., for controlling such components. Accordingly, one or more components such as the laser source 104, the beam modulator 106, the scanner 108, the stage 110, the lens actuator, the scan lens 112 (when provided as a variable-focal length lens), etc., can be considered to also include any suitable driver, as is known in the art. Each of such drivers would typically include an input communicatively coupled to the controller 122 and the controller 122 is operative to generate one or more control signals (e.g., trigger signals, etc.), which can be transmitted to the input(s) of one or more drivers associated with one or more components of the apparatus 100. Components such as the laser source 104, the beam modulator 106, the scanner 108, the stage 110, lens actuator, the scan lens 112 (when provided as a variable-focal length lens), etc., are thus responsive to control signals generated by the controller 122.

Although not shown, one or more additional controllers (e.g., component-specific controllers) may, optionally, be communicatively coupled to an input of a driver communicatively coupled to a component (and thus associated with the component) such as the laser source 104, the beam modulator 106, the scanner 108, the stage 110, the lens actuator, the scan lens 112 (when provided as a variable-focal length lens), etc. In this embodiment, each component-specific controller can be communicatively coupled to the controller 122 and be operative to generate, in response to one or more control signals received from the controller 122, one or more control signals (e.g., trigger signals, etc.), which can then be transmitted to the input(s) of the driver(s) to which it is communicatively coupled. In this embodiment, a component-specific controller may be operative as similarly described with respect to the controller 122.

In another embodiment in which one or more component-specific controllers are provided, the component-specific controller associated with one component (e.g., the laser source 104) can be communicatively coupled to the component-specific controller associated with one component (e.g., the beam modulator 106, etc.). In this embodiment, one or more of the component-specific controllers can be operative to generate one or more control signals (e.g., trigger signals, etc.) in response to one or more control signals received from one or more other component-specific controllers.

G. Back-Reflection Sensing System

As mentioned above, if the same drilling parameters are used to form blind-via holes at different locations within the dielectric substrate 24, then there will likely be some variability in the morphologies between the blind-via holes ultimately produced (e.g., due to the inherent compositional inhomogeneity of the dielectric substrate 24, surface reflectivity/thickness variations of the top conductor 20, etc.). To reduce the likelihood of undesirable morphological variability, the apparatus 100 can be provided with a back-reflection sensing system 124. The output of the back-reflection sensing system 124 can be used—either alone or in conjunction with the controller 122—to implement an adaptive processing technique in which one or more parameters (e.g., pulse width, average power, peak power, pulse energy, number or laser pulses, or the like or any combination thereof) of a process used to form a blind-via hole is set based on one or more characteristics of a back-reflection signal.

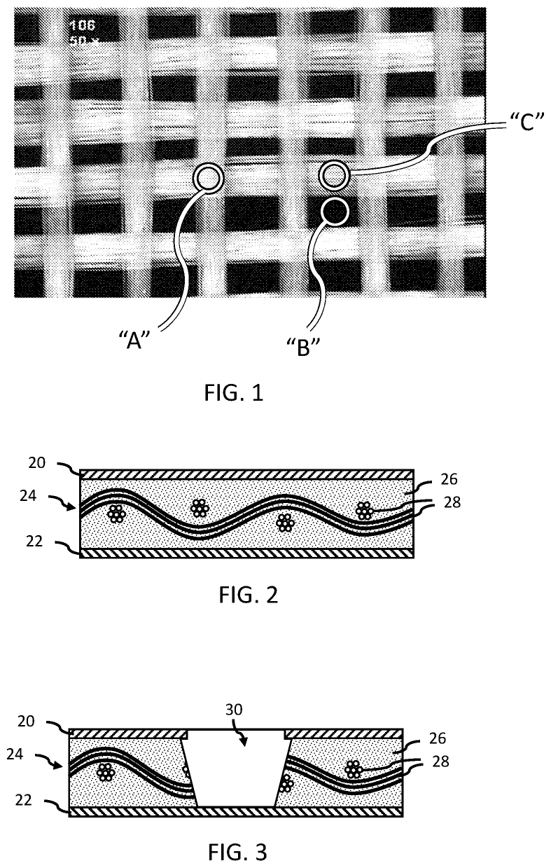

Generally, the back-reflection signal is a portion of the beam of laser energy delivered to the workpiece 102 (e.g., during a process of forming a blind-via hole) that has been reflected by the workpiece 102. Depending upon the material of the workpiece 102 that is to be processed and the wavelength of the beam of laser energy delivered to the workpiece 102 during laser processing, it is possible that the workpiece 102 can reflect at least a portion of the beam of laser energy delivered from the scan lens 112. For example, the beam of laser energy can have a wavelength of about 9.4 μm, and the workpiece 102 can be provided as a PCB such as that described above with respect to FIGS. 1 and 2. In this case, an effective proportion of the beam of laser energy delivered to the workpiece 102 can be reflected by top conductor 20 back to the scan lens 112. If the workpiece 102 (i.e., the aforementioned PCB) is to be processed to form a blind-via hole 30 terminating at the bottom conductor 22, then a portion of the beam of laser energy delivered to the bottom conductor 22 can also be reflected by the bottom conductor 22. It should also be noted that one or more constituent components of the dielectric substrate 24 (e.g., the resin material 26, the reinforcement material 28, or a combination thereof) can also reflect a portion of the beam of laser energy, but the reflected amount is typically much less than the portion that can be reflected by the top conductor 20 or bottom conductor 22.

In FIG. 4, the back-reflection sensing system 124 is illustrated as being arranged in the beam path 114 at a location between the beam modulator 106 and the scanner 108 (so as to be optically coupled to an optical output of the beam modulator 106 and an optical input of the scanner 108). Accordingly, the back-reflection sensing system 124 is operative to capture at least a portion of the back-reflection signal from a location along the beam path 114 between the beam modulator 106 and the scanner 108. It will be appreciated, however, that the back-reflection sensing system 124 may be provided to capture at least a portion of the back-reflection signal from any other suitable or desired location, or locations, along the beam path 114 (e.g., between the laser source 104 and the beam modulator 106, between the scanner 108 and the scan lens 112, between the scan lens 112 and the workpiece 102, or the like or any combination thereof.

The back-reflection sensing system 124 is also operative to convert the captured back-reflection signal into an electronic signal (also referred to herein as a “sensor signal”). Thereafter, the sensor signal can be processed (e.g., at the back-reflection sensing system 124 or the controller 122) to determine whether the workpiece 102 should be further processed to form the blind-via hole. Optionally, the sensor signal is processed (e.g., at the back-reflection sensing system 124 or the controller 122) to determine how the workpiece 102 should be further processed to form the blind-via hole. Example embodiments concerning the construction and operation of the back-reflection sensing system 124, and the processing of the sensor signal, are described in greater detail below.

### III. EXAMPLE EMBODIMENTS CONCERNING THE BACK-REFLECTION SENSING SYSTEM

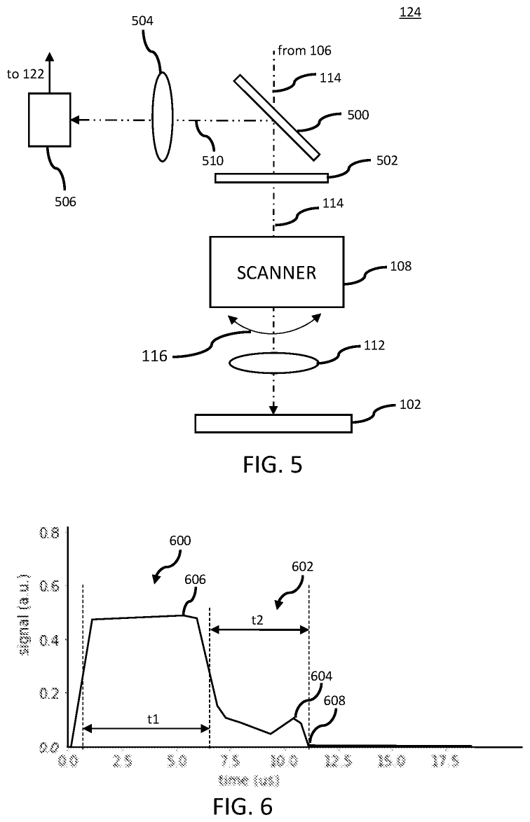

Referring to FIG. 5, the back-reflection sensing system 124 can, for example, include a polarizing beam splitter 500, a wave plate 502 (e.g., a quarter-wave plate), a lens 504 and a detector 506 (e.g., a photodetector). During a process to form a blind-via hole (e.g., as discussed above with respect to FIG. 3), a beam of laser energy propagates along beam path 114 from the beam modulator 106 and sequentially through the polarizing beam splitter 500, the wave plate 502, the scanner 108 and scan lens 112 to be delivered to the workpiece 102 (e.g., provided as a PCB as discussed above with respect to FIGS. 1 and 2).

In the illustrated embodiment, the beam of laser energy has a wavelength (e.g., ˜9.4 μm) that can be at least somewhat reflected by one or more materials of the workpiece 102. Accordingly, a portion of the delivered beam of laser energy is reflected by the workpiece 102 so as to propagate sequentially through the scan lens 112, the scanner 108 and the wave plate 502 (e.g., along a beam path 114, or along a different beam path). The reflected light is polarized by the wave plate 502 before becoming incident upon the polarizing beam splitter 500. Accordingly, the polarizing beam splitter 500 reflects the reflected light transmitted from the wave plate 502 to the lens 504 (e.g., along beam path 510, to the lens 504). The lens 504 focuses the reflected light onto the detector 506. In this case, the act of polarizing the back-reflected light at the wave plate 502 and reflecting the back-reflected light along beam path 510 during formation of a blind-via hole in the workpiece 102 constitutes “capturing” a back-reflection signal.

Generally, the detector 506 is operative to convert the incident reflected light (i.e., propagating along path 510 from lens 504) into electrical current and output the electrical current (e.g., to the controller 122) as the aforementioned sensor signal. Accordingly, the output of the detector 506 will vary depending on the intensity of the reflected light incident thereto.

### IV. DISCUSSION CONCERNING THE BACK-REFLECTION SIGNAL

FIG. 6 is a graph illustrating a signal intensity of an exemplary back-reflection signal captured by the back-reflection sensing system 124, as a function of time (i.e., during formation of a blind-via hole, according to embodiments of the present invention). Specifically, the graph shown in FIG. 6 illustrates the signal intensity of an exemplary back-reflection signal captured while an exemplary initial (i.e., first) laser pulse is delivered to the workpiece 102 (e.g., provided as a PCB as discussed above with respect to FIGS. 1 and 2) to form a blind-via hole (e.g., as discussed above with respect to FIG. 3).

For purposes of discussion, it can be assumed that the initial laser pulse, from which the captured back-reflection signal shown in FIG. 6 is based, has a pulse duration in a range between about 10 μs and 11 μs and a pulse energy sufficient to form an opening in the top conductor 22 of the PCB and remove a portion of the dielectric substrate 24 therebeneath. It will be appreciated, however, that the initial laser pulse may have a pulse duration that is less than 10 μs or more than 11 μs. According to embodiments discussed herein, the pulse energy of the initial laser pulse delivered to the workpiece 102 in a process to form a blind-via hole therein is sufficient to form an opening in the top conductor 20 by a process known as “indirect ablation” and to also remove a portion of the dielectric substrate 24 exposed by the opening by a process known as “direct ablation.”

Direct ablation of a material in the workpiece 102 occurs when the dominant cause of ablation is decomposition of the material due to absorption (e.g., linear absorption, nonlinear absorption, or any combination thereof) of energy within the beam of delivered laser energy by the material. Indirect ablation (also known as “lift-off”) of a material in the workpiece 102 occurs when the dominant cause of ablation is melting and vaporization due to heat generated in, and transported from, an adjacent material which absorbs the energy within the beam of laser energy that is ultimately delivered to the workpiece 102. Considerations concerning removal of material by indirect ablation (and direct ablation) are known in the art, and discussed in Int'l. Pub. No. WO 2017/044646 A1. In this case, while the top conductor 20 reflects a portion of the initial laser pulse delivered to the workpiece 102, top conductor 20 also heats up as a result of being irradiated by the initial laser pulse. The heat dissipates or is transferred from the top conductor 20 into a region of the dielectric substrate 24 beneath the area of the top conductor 20 that is irradiated by the initial laser pulse. Thus, over time, the region of the dielectric substrate 24 accumulates heat transferred from the top conductor 20 and is vaporized. If the irradiated area of the top conductor 20 has not attained a temperature greater than or equal to its processing threshold temperature, then vaporization of the region of the dielectric substrate 24 acts to create a pocket or space (e.g., a high-pressure region containing pressurized heated gas, particles, etc., generated upon vaporization of the dielectric substrate 24) beneath the irradiated area of the top conductor 20. Then, when area of the top conductor 20 the irradiated by the initial laser pulse attains a temperature greater than or equal to its processing threshold temperature, the pressure built up within the pocket therebelow is sufficient to eject the irradiated area of the top conductor 20 off from the workpiece, thereby “indirectly ablating” the top conductor 20 to expose the underlying dielectric substrate 24.

Referring back to FIG. 6, the back-reflection signal associated with the initial laser pulse can be characterized as including a primary intensity period 600 having a relatively high intensity followed by a secondary intensity period 602 having a relatively low intensity. In the example shown in FIG. 6, the back-reflection signal is fairly constant (e.g., at a relatively high signal intensity of about 0.5 a.u.) for roughly the first 6 μs. Then, the signal intensity drops rapidly (e.g., over a period of about 1 μs to 1.5 μs), followed by a more gradual reduction in signal intensity (e.g., over a period of about 2.5 μs) before briefly increasing again to a secondary peak 604 (e.g., to about 0.1 a.u.) and then diminishing to zero.

The evolution of the signal intensity of the back-reflection signal encodes the dynamics of the indirect ablation process involved in the formation of the blind-via hole. For example, the relatively high signal intensity in the primary intensity period 600 corresponds to the light reflected by the top conductor 20 when processing of the blind-via hole is initiated using the first laser pulse. During this time, the dielectric substrate 24 is accumulating heat transferred from the top conductor 20 and vaporizing to form a pocket of pressurized heated gas, particles, etc. The subsequent steep drop in signal intensity indicates that the irradiated area of the top conductor 20 has attained a temperature greater than or equal to its processing threshold temperature, and the pressure built up within the pocket therebelow has ejected the irradiated area of the top conductor 20, thus directly exposing the underlying dielectric substrate 24 to the initial laser pulse. Thus, the duration, t1, of the primary intensity period 600 corresponds to the time it takes for a delivered laser pulse to form an opening in the top conductor 20. The signal intensity peak 604 in the secondary intensity period 602 indicates that a portion of dielectric substrate 24 has been removed by the first laser pulse to expose a portion of the bottom conductor 22 (an act also herein referred to as forming an opening in the dielectric substrate 24). The drop to near zero signal intensity at 608 indicates the end of the laser pulse impinging on the work surface.

A. Embodiments Concerning Captured Back-Reflection Signal Characteristics

As mentioned above, the back-reflection sensing system 124 is operative to convert a back-reflection signal (i.e., captured while an initial laser pulse is delivered to the workpiece 102) into a sensor signal that represents the captured back-reflection signal. The sensor signal can be processed (e.g., at the back-reflection sensing system 124 or the controller 122, or a combination thereof) to discern one or more characteristics of the captured back-reflection signal, as can be represented by or otherwise derived from the sensor signal. It will be appreciated that the sensor signal can be processed using one or more suitable signal processing techniques as known in the art to discern one or more captured back-reflection signal characteristics. Example embodiments of such characteristics of the captured back-reflection signal are described in greater detail below.

i. Duration of Primary Intensity Period

One embodiment of a characteristic of the captured back-reflection signal that can be used to make a processing determination is the duration, t1, of the primary intensity period 600. In FIG. 6, the duration of the primary intensity period 600 is measured based on the full-width at half-maximum (FWHM) of the signal intensity of the captured back-reflection signal versus time. In another embodiment, however, the primary intensity period may be considered as coinciding with the end of the pulse rise time of the initial laser pulse from which the back-reflection signal is captured. The pulse rise time can be considered as the interval of time required for the leading edge of a laser pulse to rise from 10% to 90% of the peak pulse amplitude. As also shown in FIG. 6, the duration, t2, represents the period beginning at the end of the primary intensity period 600 to the end of the laser pulse.

Given the definitions of durations t1 and t2 above, it should be apparent that, as t1 decreases, t2 will increase. And as t1 increases, t2 will decrease. Experiments conducted by the Applicant tend to indicate that blind via holes associated with captured back-reflection signals having a relatively short t1 duration (i.e., a relatively long t2 duration) tend to have undesirably large overhang, and that blind via holes associated with captured back-reflection signals having a relatively long t1 duration (i.e., a relatively short t2 duration) tend to have undesirably large taper.

ii. Integration of Region in Secondary Intensity Period

Another embodiment of a characteristic of the captured back-reflection signal that can be used to make a processing determination is the integrated area under the signal from the end of t1 to the end of the laser pulse, which captures both the secondary peak 604 (indicating formation of an opening in the dielectric substrate 24) and the total length of time that laser energy was directed to the dielectric substrate 24.

iii. Other Example Embodiments of Captured Back-Reflection Signal Characteristics

Other embodiments of characteristics of the captured back-reflection signal that can be used to make a processing determination include: the signal intensity at the secondary peak (e.g., 604 as shown in FIG. 6) of the captured back-reflection signal; and the signal intensity at a primary peak (i.e., highest signal intensity) of the captured back-reflection signal (e.g., 606 as shown in FIG. 6).

B. Embodiments Concerning Comparison Between Captured and Reference Back-Reflection Signal Characteristics

Once discerned, a captured back-reflection signal characteristic (or other data representing the same) can be compared (e.g., at the back-reflection sensing system 124 or the controller 122, or a combination thereof) to a reference back-reflection signal characteristic associated with that captured back-reflection signal characteristic. For example, if the captured back-reflection signal characteristic is the aforementioned duration, t1, of the primary intensity period, then the associated reference back-reflection signal characteristic would be some reference value or range for the duration, t1, of the primary intensity period. If the captured back-reflection signal characteristic is the aforementioned integrated area under the signal during the secondary intensity period, then the associated reference back-reflection signal characteristic would be some reference value or range for the integrated area.

It will be appreciated that such comparisons can be made by processing the sensor signal (e.g., using one or more suitable signal processing techniques as known in the art), by processing data associated with the discerned characteristic(s), or the like or any combination thereof. It will further be appreciated that the reference value or range of the associated reference back-reflection signal characteristic may correspond to one or more parameters (e.g., in terms of duration, peak power, spot size, wavelength, etc.) of the portion of the initial laser pulse that has been delivered to the workpiece 102 up to the point when the back-reflection signal characteristic was captured, one or more parameters of the workpiece 102 (e.g., material composition of the top conductor 20, thickness of the top conductor 20, material composition of the dielectric substrate 24, thickness of the dielectric substrate 24, etc.), or the like or any combination thereof. For example, the reference value or range for the duration, t1, of the primary intensity period may: (a) decrease with increasing peak power of the initial laser pulse or increase with decreasing peak power of the initial laser pulse; increase with increasing thickness of the top conductor 20 or decrease with decreasing thickness of the top conductor 20; or (b) decrease if the top conductor 20 is coated with an energy-absorbing coating, or (c) may increase or decrease depending on the composition of the matrix material 26; or (d) the like or any combination thereof. These reference values or ranges may be derived or otherwise specified through empirical observations, computational simulations or diagnostics, or the like or any combination thereof.

### V. EMBODIMENTS CONCERNING ADAPTIVE PROCESSING

The apparatus 100 can be used to implement an adaptive processing technique in which one or more parameters (e.g., pulse width, average power, peak power, pulse energy, number or laser pulses, or the like or any combination thereof) of a process used to form a blind-via hole is set based on the aforementioned comparison of the captured back-reflection signal characteristic (or other data representing the same) to the associated reference back-reflection signal characteristic. In this case, the process used to form a blind-via hole can be generally characterized as a “punch” process requiring at least one laser pulse to be delivered to a single desired location at the workpiece 102 (i.e., provided as the aforementioned PCB described with respect to FIGS. 1 and 2). The first laser pulse to be delivered to the workpiece 102 to form a particular blind-via hole is herein referred to as the “initial laser pulse.” Any subsequent laser pulses delivered to the workpiece 102 to form the particular blind-via hole is herein referred to as a “supplemental laser pulse,” or may be otherwise labeled depending on the order in the sequence of laser pulses delivered to the workpiece 102 to form the particular blind-via hole (e.g., “second laser pulse,” “third laser pulse,” “final laser pulse,” etc.).

The initial laser pulse, as it is to be delivered to the workpiece 102, will be characterized by a set of laser pulse parameters (also referred to herein as “initial laser pulse parameters”) such as wavelength, pulse duration, temporal optical power profile, the peak power associated with the temporal optical power profile, spot size, and pulse energy. Generally, the pulse duration of any laser pulse can be adjusted by controlling an operation of the laser source 104 in any manner known in the art, by controlling an operation of the beam modulator 106 (e.g., to effect pulse slicing, as described above), or the like or any combination thereof. Examples of temporal optical power profiles that the initial laser pulse may have include rectangular, chair-shaped (from low to high, from high to low, or a combination thereof), ramped (increasing and/or decreasing, either stepwise or linearly or non-linearly continuous, or a combination thereof). The temporal optical power profile (and, thus, peak power) of any laser pulse can be adjusted by controlling an operation of the laser source 104 in any manner known in the art, by controlling an operation of the beam modulator 106, or the like or any combination thereof.

Generally, the initial laser pulse parameters are set so that a blind-via hole (e.g., blind-via hole 30, as exemplarily shown in FIG. 3) with desirable characteristics (e.g., in terms of overhang, taper, or the like or any combination thereof) can be formed at a reference location within the workpiece 102 using only the initial laser pulse. The reference location can, for example, be a location in the workpiece 102 corresponding to a location such as location “B” or location “C” (both shown in FIG. 1) or the like. The setting of initial laser pulse parameters can thus vary depending on the construction of the workpiece 102, and the determination of the reference pulse energy amount can be determined empirically or computationally. One or more of the aforementioned back-reflection signal characteristics (e.g., duration, t1, of the primary intensity period, integrated area under the signal during the secondary intensity period, etc.) may then be empirically determined (e.g., directing a laser pulse having the initial laser pulse parameters to the workpiece 102 and capturing and processing the resultant captured back-reflection signal, as discussed above), computationally derived, or the like or any combination thereof and set as the reference value or range of the back-reflection signal characteristic(s) associated with an initial laser pulse to be delivered to the workpiece 102 during a “punch” process to form a blind-via hole at an arbitrary location in the workpiece 102.

In one embodiment, the initial laser pulse, as delivered to the workpiece 102, can have a wavelength in a range from 9 μm (or thereabout) to 11 μm (or thereabout) (e.g., a wavelength of 9.4 μm (or thereabout), 10.6 μm (or thereabout), or the like), a pulse duration in a range from 5 μs (or thereabout) to 20 μs (or thereabout), a temporal optical power profile that is rectangular (or at least substantially rectangular), a peak power in a range from 250 W (or thereabout) to 2 kW (or thereabout) and a spot size in a range from 30 μm (or thereabout) to 90 μm (or thereabout). It will also be appreciated that the initial laser pulse, as delivered to the workpiece 102, can have a wavelength below 9 μm (e.g., in the ultraviolet or green-visible ranges of the electromagnetic spectrum), provided that other characteristics (e.g., pulse duration, temporal optical power profile, peak power, spot size, pulse energy, etc.) are set such that the initial laser pulse can process the workpiece 102. It should be noted that, if the wavelength is changed to the ultraviolet or green-visible ranges of the electromagnetic spectrum, the initial laser pulse may be replaced with an initial set of laser pulses, wherein each laser pulse in the initial set of laser pulses has a pulse duration in the ns or ps regime (e.g., in a range between 10 ns (or thereabout) and 1 μs (or thereabout)) and the laser pulses are delivered at a pulse repetition rate in a range from 100 MHz (or thereabout) to 5 GHz (or thereabout).

To implement an adaptive processing technique for executing a “punch” process to form the blind-via hole at an arbitrary location in the workpiece 102, the initial laser pulse (i.e., having the initial laser pulse parameters) is delivered to the workpiece 102. At least a portion of the light in the initial laser pulse is reflected by the workpiece 102 (i.e., by the top conductor 20) back through the scan lens 112 and thereafter captured as discussed above with respect to FIG. 5. The resultant captured back-reflection signal is then processed (e.g., as discussed above) to discern one or more captured back-reflection signal characteristics (or other data representing the same) associated with the initial laser pulse. Such characteristic(s) can then be compared (e.g., at the back-reflection sensing system 124, at the controller 122, or the like or any combination thereof) against one or more associated reference back-reflection signal characteristics (e.g., as discussed above). As will be described in greater detail below, the controller 122 is operative to control an operation of one or more components of the apparatus 100 (e.g., the laser source 104, the beam modulator 106, or the like or any combination thereof) based on the comparison.

In some embodiments, the captured back-reflection signal characteristic associated with the initial laser pulse is the duration, t1, of the primary intensity period. Accordingly, the duration, t1, of the primary intensity period is compared to the predetermined reference value or range of the duration, t1, of the primary intensity period. In some embodiments, the captured back-reflection signal characteristic associated with the initial laser pulse is the integrated area under the signal during the secondary intensity period. Accordingly, the integrated area under the signal during the secondary intensity period is compared to the predetermined reference value or range of the integrated area under the signal during the secondary intensity period. In other embodiments, the captured back-reflection signal characteristic associated with the initial laser pulse is a combination of the aforementioned characteristics. Accordingly, the captured characteristics are compared to the predetermined reference values or ranges for those characteristics, respectively.

If the duration, t1, of the primary intensity period associated with the initial laser pulse is greater than the reference value or range associated therewith, then this indicates that the initial laser pulse (i.e., having the initial laser pulse parameters) will not be sufficient to either form an opening in the top conductor 20 or form a blind-via hole with desirable characteristics (e.g., in terms of taper). If the duration, t1, of the primary intensity period of the initial laser pulse is less than the reference value or range associated therewith, then this indicates that the initial laser pulse will either not be sufficient to form a blind-via hole with desirable characteristics (e.g., in terms of overhang) or may end up damaging (e.g., undesirably melting or removing) the bottom conductor 22 exposed within the from the blind-via hole.

If a comparison between a captured back-reflection signal characteristic and an associated reference value or range indicates that the initial laser pulse will not be sufficient to form a blind-via hole with desirable characteristics (e.g., as discussed above), then the controller 122 can output one or more control signals (e.g., to the laser source 104, the beam modulator 106, or the like or any combination thereof) to ensure that a blind-via hole with desirable characteristics (e.g., in terms of taper and overhang) will be formed. For example, as will be appreciated (e.g., from FIG. 6), the duration, t1, of the primary intensity period and the integrated area under the signal during the secondary intensity period can be discerned from the captured back-reflection signal associated with the initial laser pulse before the entire initial laser pulse has been delivered to the workpiece 102. Thus, the one or more control signals output by the controller 122 can be operative to modify the initial laser pulse parameters (e.g., to adjust the temporal optical power profile by increasing or decreasing the instantaneous power of the initial laser pulse, to increase or decrease the pulse duration of the initial laser pulse, or the like or any combination thereof). Instead of, or in addition to, modifying the initial laser pulse parameters of the initial laser pulse, one or more control signals output by the controller 122 can be operative to cause one or more supplemental laser pulses to be delivered to the workpiece 102 after the entire initial laser pulse has been delivered to the workpiece 102. As used herein, the modification of one or more initial laser pulse parameters or delivery of supplemental laser pulses, as initiated by the controller 122 (e.g., upon the output of one or more control signals by the controller 122 as a result of the aforementioned comparison), is herein referred to as an “adaptive response” to the captured back-reflection signal characteristic(s).

If the duration, t1, of the primary intensity period duration associated with the initial laser pulse is greater than the reference value or range associated therewith, then the controller 122 is operative to cause the temporal optical power profile to be adjusted (e.g., by increasing the instantaneous power of the initial laser pulse) and/or the pulse duration of the initial laser pulse to be increased. In one embodiment, the aforementioned laser pulse parameters are adjusted in a predetermined manner regardless of how much greater the duration, t1, of the primary intensity period of the initial laser pulse is relative to the reference value or range associated therewith. In another embodiment, the aforementioned laser pulse parameters are adjusted in a predetermined manner that corresponds to the difference between the duration, t1, of the primary intensity period of the initial laser pulse relative to the reference value or range associated therewith. If one or more supplemental laser pulses are caused to be delivered to the workpiece 102, then any of those supplemental laser pulses may be characterized by laser pulse parameters that are the same as the initial laser pulse parameters or different from the initial laser pulse parameters (e.g., to decrease the rate at which the dielectric substrate 24 is removed by a supplemental laser pulse). Generally, the manner with which the adaptive response is executed by the controller 122 can be predetermined (e.g., based on empirical observations, computational simulations, or the like or any combination thereof) or can be determined in real-time (e.g., by interpolation of predetermined data), or the like or any combination thereof.

If the duration, t1, of the primary intensity period associated with the initial laser pulse is less than the reference value or range associated therewith, then the controller 122 is operative to cause the temporal optical power profile to be adjusted (e.g., by decreasing the instantaneous power of the initial laser pulse) and/or the pulse duration of the initial laser pulse to be decreased. In one embodiment, the aforementioned laser pulse parameters are adjusted in a predetermined manner regardless of how much less the duration, t1, of the primary intensity period of the initial laser pulse is relative to the reference value or range associated therewith. In another embodiment, the aforementioned laser pulse parameters are adjusted in a predetermined manner that corresponds to the difference between the duration, t1, of the primary intensity period of the initial laser pulse relative to the reference value or range associated therewith. If one or more supplemental laser pulses are caused to be delivered to the workpiece 102, then any of those supplemental laser pulses may be characterized by laser pulse parameters that are the same as the initial laser pulse parameters or different from the initial laser pulse parameters (e.g., to increase the rate at which the dielectric substrate 24 is removed by a supplemental laser pulse). Generally, the manner with which the adaptive response is executed by the controller 122 can be predetermined (e.g., based on empirical observations, computational simulations, or the like or any combination thereof) or can be determined in real-time (e.g., by interpolation of predetermined data), or the like or any combination thereof.

### VII. CONCLUSION

The foregoing is illustrative of embodiments and examples of the invention, and is not to be construed as limiting thereof. For example, although adaptive processing techniques have been discussed above with respect to a blind-via hole formation process, it will be appreciated that these adaptive processing techniques may be extended to through-via hole processing techniques, or the like. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

What is claimed is:

1. A laser-processing apparatus for carrying out a process to form a via in a workpiece, having a first material formed on a second material, by directing laser energy onto the workpiece such that the laser energy is incident upon the first material, wherein the laser energy has a wavelength to which the first material is more reflective than the second material, the apparatus comprising:
a back-reflection sensing system operative to capture a back-reflection signal corresponding to a portion of laser energy directed to the workpiece and reflected by the first material and generate a sensor signal based on the captured back-reflection signal; and
a controller communicatively coupled to an output of the back-reflection sensing system, wherein the controller is operative to control a remainder of the process by which the via is formed based on the sensor signal.

2. The laser-processing apparatus of claim 1, wherein the laser energy directed to the workpiece is manifested as at least one laser pulse and wherein the controller is operative to control the process, at least in part, by controlling a pulse energy of the least one laser pulse.

3. The laser-processing apparatus of claim 1, wherein the laser energy directed to the workpiece is manifested as at least one laser pulse and wherein the controller is operative to control the process, at least in part, by controlling a pulse width of the least one laser pulse.

4. The laser-processing apparatus of claim 1, wherein the laser energy directed to the workpiece is manifested as at least one laser pulse and wherein the controller is operative to control the process, at least in part, by controlling the number of laser pulses to be directed to the workpiece.

5. The laser-processing apparatus of claim 1, wherein the controller is operative to control the process, at least in part, by controlling an average power of the laser energy.

6. The laser-processing apparatus of claim 1, wherein the controller is operative to control the process, at least in part, by controlling a peak power of the laser energy.

7. The laser-processing apparatus of claim 1, wherein the laser energy directed to the workpiece is manifested as a laser pulse and wherein the controller is operative to control the process by which the via is formed while the laser pulse is directed to the workpiece.

8. The laser-processing apparatus of claim 1, further comprising a laser source operative to generate the laser energy.

9. The laser-processing apparatus of claim 1, further comprising a beam modulator operative to modulate the laser energy.

10. A method comprising:
carrying out a process to form a via in a workpiece, having a first material formed on a second material, by directing a laser pulse onto the workpiece such that the laser pulse is incident upon the first material, wherein the laser energy has a wavelength to which the first material is more reflective than the second material;
capturing a back-reflection signal corresponding to a portion of laser energy directed to the workpiece and reflected by the first material;
generating a sensor signal based on the based on the captured back-reflection signal;
processing the sensor signal to determine how a remainder of the process should be carried out to form the via; and
carrying out the remainder of the process based on the processing of the sensor signal.

11. The method of claim 10, wherein the laser energy directed to the workpiece is manifested as at least one laser pulse and wherein carrying out the remainder of the process includes adjusting a pulse energy of the least one laser pulse.

12. The method of claim 10, wherein the laser energy directed to the workpiece is manifested as at least one laser pulse and wherein carrying out the remainder of the process includes adjusting a pulse width of the least one laser pulse.

13. The method of claim 10, wherein the laser energy directed to the workpiece is manifested as at least one laser pulse and wherein carrying out the remainder of the process includes adjusting the number of laser pulses to be directed to the workpiece.

14. The method of claim 10, wherein carrying out the remainder of the process includes adjusting an average power of the laser energy.

15. The method of claim 10, wherein carrying out the remainder of the process includes adjusting a peak power of the laser energy.

16. The method of claim 10, wherein the laser energy directed to the workpiece is manifested as a laser pulse and wherein the remainder of the process is carried out while the laser pulse is directed to the workpiece.

17. A non-transitory computer-readable medium for use with a laser-processing apparatus operative to carry out a process to form a via in a workpiece, having a first material formed on a second material, by directing laser energy onto the workpiece such that the laser energy is incident upon the first material, wherein the laser energy has a wavelength to which the first material is more reflective than the second material, wherein apparatus has a back-reflection sensing system operative to capture a back-reflection signal corresponding to a portion of laser energy directed to the workpiece and reflected by the first material and generate a sensor signal based on the captured back-reflection signal and a controller communicatively coupled to an output of the back-reflection sensing system, and wherein the non-transitory computer-readable medium has stored thereon instructions which, when executed by the controller, causes the controller to control the process by which the via is formed based on the sensor signal.
